(19) United States
(12) Patent Application Publication
(10) Pub. No.: US 2026/0271620 A1
(43) Pub. Date: Sep. 10, 2026

(54) THERMOELECTRIC MODULE

(71) Applicant: KYOCERA Corporation, Kyoto-shi, Kyoto (JP)

(72) Inventor: Yuki HAMADA, Kirishima-shi, Kagoshima (JP)

(73) Assignee: KYOCERA Corporation, Kyoto-shi, Kyoto (JP)

(21) Appl. No.: 18/869,270

(22) PCT Filed: May 12, 2023
(86) PCT No.: PCT/JP2023/017994

§ 371 Date: Nov. 25, 2024

(30) Foreign Application Priority Data
May 31, 2022 (JP) 2022-088801

(51) Int. Cl. H10N 19/00; H05K 1/181

(52) U.S. Cl. CPC H10N 19/101; H05K 1/181; H05K 2201/10189; H05K 2201/10219

(57) ABSTRACT

Support substrates, thermoelectric elements, and wiring conductors are provided. The support substrates include a first substrate and a second substrate which are located to face each other. The wiring conductors are located on the first substrate and the second substrate. The thermoelectric elements are located in contact with the wiring conductors facing each other. The first substrate includes a first region in which the thermoelectric elements are located. The first substrate includes a second region located subsequent to the first region. The wiring conductors include an extended portion extending over the second region. A connector is further provided, and a surface of the connector facing the support substrate is surface-connected to the extended portion.

### TECHNICAL FIELD

The present disclosure relates to a thermoelectric module for use in temperature adjustment, for example, temperature adjustment for seat coolers of motor vehicles, fuel cells, lithium ion batteries, or the like.

### BACKGROUND OF INVENTION

As a thermoelectric module, for example, a thermoelectric power generation module described in Patent Document 1 is known. The thermoelectric power generation module described in Patent Document 1 includes a pair of substrates disposed to face each other, electrodes respectively located on surfaces of the pair of substrates facing each other, a plurality of thermoelectric elements disposed between surfaces of the pair of substrates facing each other so as to be electrically connected to each other by the electrodes, and a lead wire for electrically connected to a thermistor, and the electrode and the lead wire are connected to each other via an electrically conductive bonding material.

### CITATION LIST

### Patent Literature

Patent Document 1: JP 2021-113636 A

### SUMMARY

A sample holder of the present disclosure includes support substrates, thermoelectric elements, and wiring conductors. The support substrates include a first substrate and a second substrate which are located to face each other. The wiring conductors are located on the first substrate and the second substrate. The thermoelectric elements are located in contact with the wiring conductors facing each other. The first substrate includes a first region in which the thermoelectric elements are located. The first substrate includes a second region located subsequent to the first region. The wiring conductors include an extended portion extending over the second region. Further, a connector is further provided, and a surface of the connector facing the support substrate is surface-connected to the extended portion.

### BRIEF DESCRIPTION OF THE DRAWINGS

FIG. 1 is a perspective view illustrating an example of a thermoelectric module.

FIG. 2 is a side view of the thermoelectric module illustrated in FIG. 1.

FIG. 3 is a side view illustrating another example of the thermoelectric module.

FIG. 4 is a side view illustrating another example of the thermoelectric module.

FIG. 5 is an enlarged plan view of the thermoelectric module illustrated in FIG. 4.

FIG. 6 is a bottom view illustrating another example of the thermoelectric module.

FIG. 7 is a perspective view illustrating another example of the thermoelectric module.

FIG. 8 is a side view of another example of the thermoelectric module when viewed from a lead member.

FIG. 9 is a plan view illustrating another example of the thermoelectric module.

FIG. 10 is a perspective view illustrating another example of the thermoelectric module.

FIG. 11 is a side view illustrating another example of the thermoelectric module.

FIG. 12 is a side view illustrating another example of the thermoelectric module.

### DESCRIPTION OF EMBODIMENTS

A thermoelectric module 100 will be described in detail.

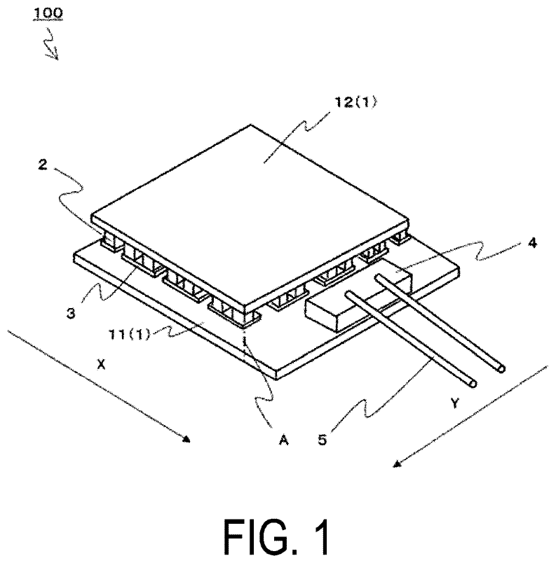

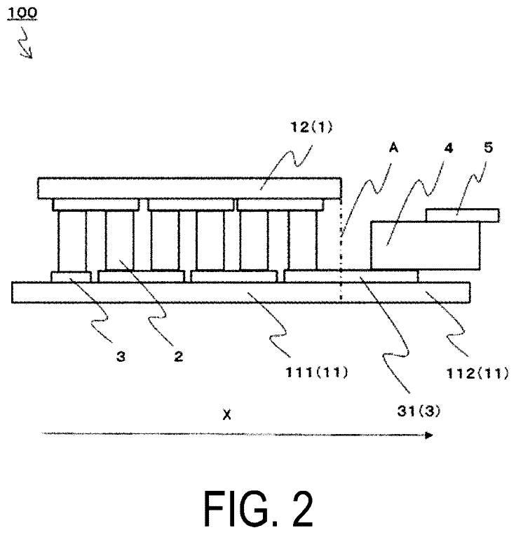

FIG. 1 is a perspective view illustrating an example of the thermoelectric module 100, and FIG. 2 is a side view of the thermoelectric module 100 illustrated in FIG. 1. As illustrated in FIG. 1, the thermoelectric module 100 includes support substrates 1, thermoelectric elements 2, wiring conductors 3, a connector 4, and lead members 5. Specifically, the support substrates 1 include a first substrate 11 and a second substrate 12 facing each other, and the wiring conductors 3 are located on each of surfaces of the first substrate 11 and the second substrate 12 facing each other. The thermoelectric elements 2 are located in contact with the wiring conductors 33 so as to be electrically connected thereto.

As illustrated in FIG. 2, the first substrate 11 and the second substrate 12 include a first region 111 in which the thermoelectric elements 2 are located, and the first substrate 11 includes a second region 112 located subsequent to the first region 111. Furthermore, the wiring conductors 3 include extended portions 31 extending over the second region 112. Further, a connector 4 is provided, and a surface of the connector 4 facing the support substrate 1 is surface-connected to the extended portions 31.

Next, functions and features of members constituting the thermoelectric module 100 will be described. In describing the members, as illustrated in FIGS. 1 and 2, a direction from the first region 111 toward the second region 112 is defined as a first direction (X), and a direction orthogonal to the first direction is defined as a second direction (Y).

The support substrate 1 is a member for cooling and heating an external device or the like by electrical connection between the thermoelectric element 2 and the wiring conductor 3. In FIGS. 1 and 2, a substrate located blow is the first substrate 11, and a substrate located upper is the second substrate 12. For ease of understanding, in all the drawings, a virtual line (two dot chain line) is provided at a boundary A between the first region 111 and the second region 112.

The first substrate 11 and the second substrate 12 have, for example, a rectangular shape. As a material of the first substrate 11 and the second substrate 12, a configuration is used in which, for example, a metal plate such as copper is laminated to an outer main surface of an insulating substrate body made of an epoxy resin material to which an alumina filler is added or a ceramic material such as alumina or aluminum nitride. Alternatively, a configuration may be used in which an insulating material is provided on a main surface of an inner side of a substrate body made of a conductive material such as silver or copper.

The support substrate 1 can perform heat absorption (cooling) in the first substrate 11 and heat generation (heating) in the second substrate 12 or can perform heat generation (heating) in the first substrate 11 and heat absorption (cooling) in the second substrate 12 by the Peltier effect.

A plurality of the thermoelectric elements 2 are provided so as to be electrically connected by the wiring conductors 3. The plurality of thermoelectric elements 2 include p-type thermoelectric elements and n-type thermoelectric elements. The thermoelectric elements 2 are arranged vertically and horizontally at intervals, for example, from 0.1 times to 2 times the diameter of the thermoelectric element 2 and are bonded to the wiring conductors 3, respectively, with solder. In the thermoelectric elements 2, the p-type thermoelectric elements and the n-type thermoelectric elements are alternately arranged adjacent to each other. The thermoelectric element 2 has, for example, a cylindrical shape. Other shapes include a prismatic shape.

The wiring conductors 3 are located in contact with portions of the first substrate 11 and the second substrate 12, facing each other. The shape of the wiring conductor 3 can be appropriately adjusted according to the arrangement of the thermoelectric elements 2. The material of the wiring conductor 3 is not limited to copper, and may be, for example, silver or silver-palladium.

The connector 4 can hold a warpage of the support substrate 1 while holding the electrical connection to the wiring conductors 3. The connector 4 has, for example, a rectangular shape. As illustrated in FIG. 2, the surface of the connector 4 facing the support substrate 1 is surface-connected to the extended portions 31 of the wiring conductors 3. The connector 4 is made of a resin material such as polybutylene terephthalate (PBT), polycarbonate (PC), polyphenylene sulfide (PPS), liquid crystal polymer (LCP), nylon, polyetheretherketone (PEEK), or polyamide (PA).

The lead member 5 is electrically connected to an external power supply via the connector 4. The lead member 5 is made of a material including a metal material such as copper, iron, or aluminum. The lead member 5 has a circular rod shape in FIG. 1. However, various shapes such as a plate shape can be adopted from the viewpoint of design. The lead member 5 is bonded with solder.

Other examples include a conductive wire covered with a resin member to be formed into a band shape in order to enhance insulation properties.

As illustrated in FIGS. 1 and 2, the thermoelectric module 100 according to the present embodiment includes the connector 4.

When a current flows through the thermoelectric module 100, a stress is applied to a connecting portion between the wiring conductors 3 and the connector 4. However, in the thermoelectric module 100 of the present disclosure, the connector 4 that is surface-connected is disposed, and thus the applied stress is small. Thus, cracks are less likely to occur in the connecting portion. As a result, the thermoelectric module 100 of the present disclosure is excellent in durability.

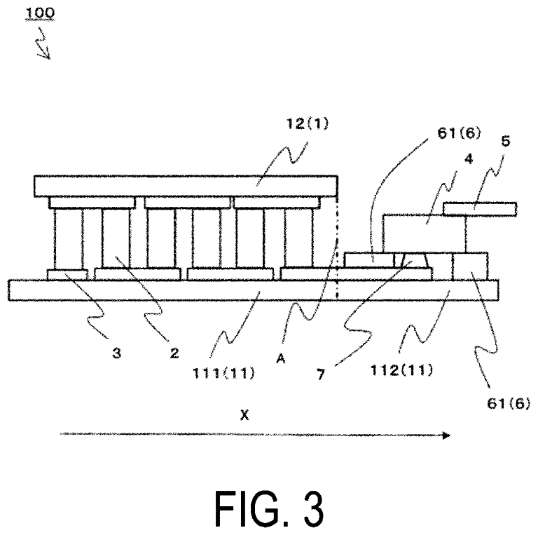

As illustrated in FIG. 3, the connector 4 may be fixed to the support substrate 1 via a fixing member 6. Thus, parallelism of the connector 4 can be maintained as compared with a case of being fixed without the fixing member 6. In addition, by interposing the fixing member 6, the possibility that the connector 4 is peeled off when repeatedly used can be reduced. As a result, the thermoelectric module 100 of the present disclosure is excellent in durability.

The fixing member 6 is located between the wiring conductor 3 and the connector 4. The fixing member 6 is made a material including an epoxy resin. The fixing member 6 has a frame-like shape in accordance with the second region 112 in FIG. 3. However, various shapes such as a plate shape can be adopted from the viewpoint of design.

As illustrated in FIG. 3, electrically conductive bonding materials 7 may be used for the electrical connection between the wiring conductors 3 and the connector 4. Thus, a height difference between the connector 4 and the wiring conductors 3 can be adjusted at the time of connection with the connector 4. As a result, the thermoelectric module 100 of the present disclosure is excellent in durability. As illustrated in FIG. 3, a case where the wiring conductors 3 and the connector 4 are bonded to each other by the electrically conductive bonding materials 7 with a certain surface also means “surface-connected”.

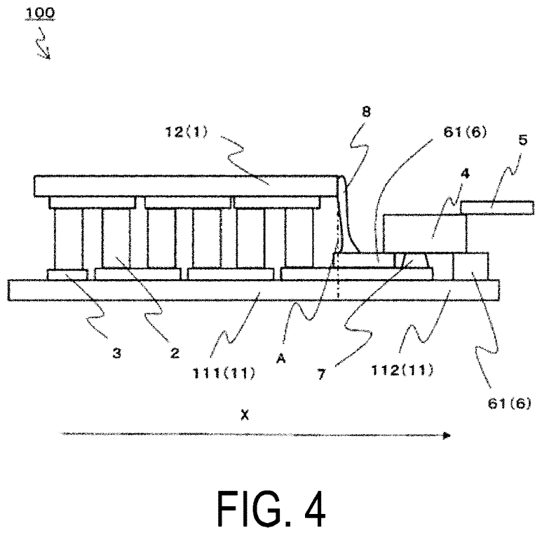

As illustrated in FIG. 3 or 4, the fixing member 6 may include a surrounding portion 61 surrounding the electrically conductive bonding materials 7, and the connector 4 may be placed on the surrounding portion 61. Specifically, the fixing member 6 may be located so as to surround at least an outer edge of the connector 4 in a plan view. Thus, by providing the surrounding portion 61, the connector 4 can be placed more stably. In addition, a certain region in which the electrically conductive bonding materials 7 are discharged can be formed by the surrounding portion 61. Thus, the amount of the electrically conductive bonding materials 7 can be made constant, and the bonding strength of the thermoelectric module 100 is less likely to vary from product to product. As a result, the thermoelectric module 100 of the present disclosure is excellent in reliability.

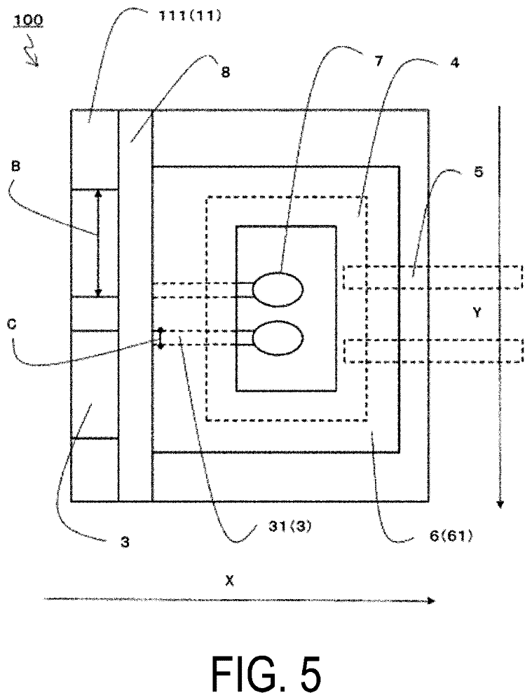

As illustrated in FIG. 5, a width (line C) of the extended portion 31 may be smaller than a width (line B) of the wiring conductor 3 located in the first region 111. In the thermoelectric module 100, the wiring conductors 3 may be heated during the electrical connection. Thus, when connected to the wiring conductors 3, thermal stress may occur and the cracks may occur. Thus, when the width (line C) of the extended portion 31 is smaller than the width (line B) of the wiring conductor 3 located in the first region 111, even when the thermal stress occurs, the thermal stress is small, and thus the cracks are less likely to occur in the connecting portion. As a result, the thermoelectric module 100 of the present disclosure is excellent in durability. By reducing the width, a degree of freedom of a position of the wiring conductor 3 in the second region 112 can be increased. As a result, the thermoelectric module 100 of the present disclosure can be adjusted in accordance with dimensions of the connector 4 and the support substrate 1, and thus the thermoelectric module 100 is excellent in reliability. In the case illustrated in FIG. 5, the width of the wiring conductor 3 and the width of the extended portion 31 located in the first region 111 are considered to be from 1 mm to 45 mm and from 0.6 mm to 15 mm, respectively. For ease of understanding, in FIG. 5, the connector 4 and the lead members 5 are indicated by dashed lines.

As illustrated in FIGS. 4 and 5, the extended portions 31 may be covered with a resin 8 at a portion near the first region 111 other than a portion overlapping the connector 4 in a plan perspective view, and the resin 8 may cover a portion between the first substrate 11 and the second substrate 12 and facing the connector 4. Since the thermoelectric elements 22 are covered with the resin 8, the thermoelectric elements 22 are less likely to be exposed to the outside air, and the possibility of occurrence of the cracks due to oxidation can be reduced. As a result, the thermoelectric module 100 of the present disclosure is excellent in durability.

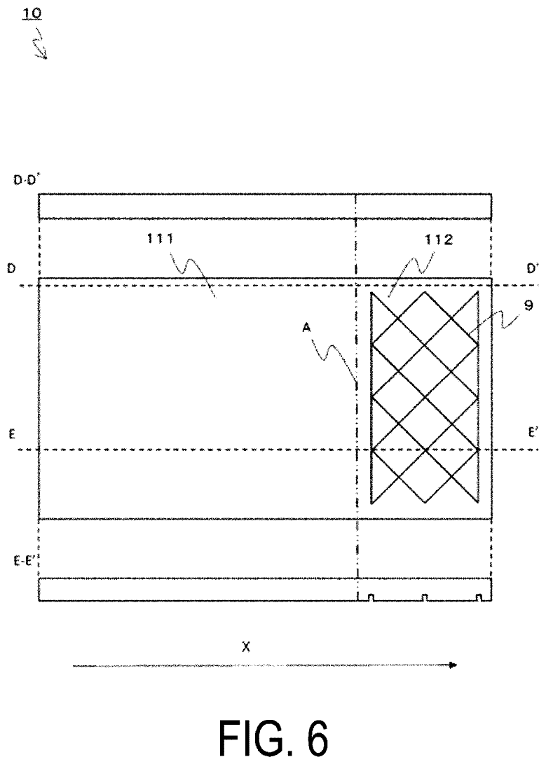

As illustrated in FIG. 6, the first substrate 11 may include slits 9 in a lattice shape at a position facing the second region 112. By providing the slits 9, the second region 112 is likely to be deformed, and the stress applied to the boundary A is further reduced. As a result, the thermoelectric module 100 of the present disclosure is excellent in durability.

The term “slit” as used herein means a narrow cut as illustrated in FIG. 6.

A pattern of the slits 9 as an example will be described below. As illustrated in FIG. 6, two slits 9 extending in the Y direction are provided on the opposite side of the second region 112, and slits 9 extending in a lattice shape are provided between the two slits 9. At this time, when the slits 9 are provided so as to be oriented at 45 degrees with respect to the X direction and the Y direction, the stress applied to the boundary A is likely to be further reduced.

When terminal ends of each of the slits 9 in the lattice shape are located in the two slits 9, respectively, extending in the Y direction and the slits 9 are connected to each other, the stress generated in the boundary A can be most relaxed. When an interval of the lattice is equal, the stress applied to the boundary A is likely to be further smaller.

As illustrated in FIG. 6, the slits 9 may be located inside the second region 112. For ease of understanding, FIG. 6 illustrates cross-sectional views of two portions of the first substrate 11 of a portion (D-D′) not including the slit 9 and a portion (E-E′) including the slits 9.

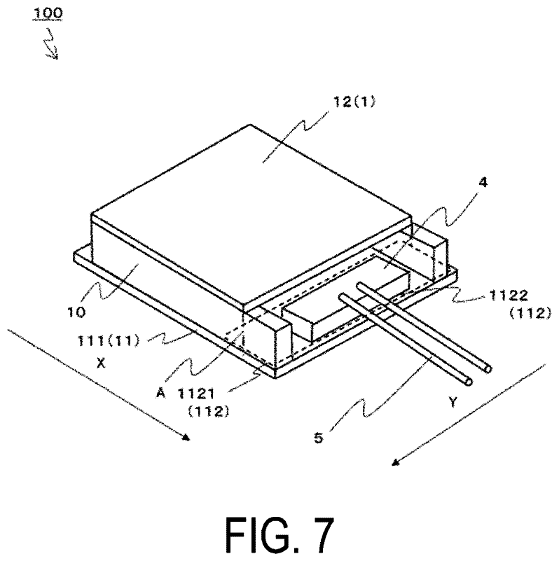

As illustrated in FIG. 7, the second region 112 may include a fitting portion 1121 of the connector 4, and the fitting portion 1121 may include side walls 10 located along a direction in which the extended portion extends with sandwiching a fitting region 1122 to which the connector 4 is fitted. Thus, the connector 4 is sandwiched between the side walls 10, and thus movement in a direction parallel to the second direction (Y) during use can be reduced. As a result, the thermoelectric module 100 of the present disclosure is excellent in durability. In FIG. 7, the fitting portion 1121 is indicated by a dashed line.

The side wall 10 is made of a resin material including epoxy, acrylic, or silicone. As illustrated in FIG. 7, the side walls 10 face each other in the second direction (Y) and are each in contact with the first substrate 11 and the second substrate 12, and at least a part of each of the side walls 10 is located from the first region 111 to the second region 112.

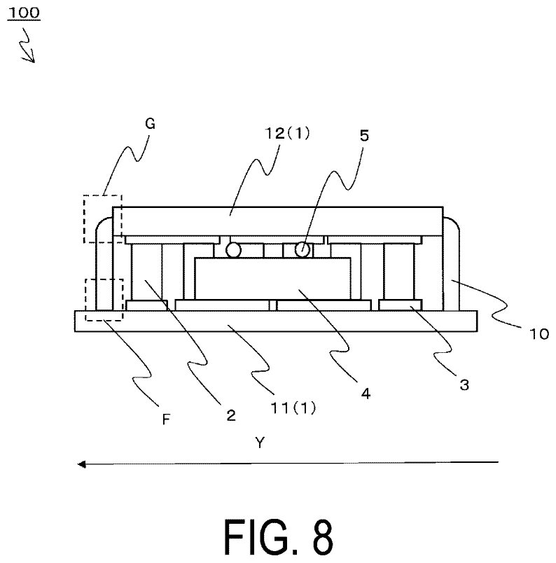

FIG. 8 illustrates a side view of the thermoelectric module 100 when viewed from the lead member 5 as another example. As illustrated by a portion F illustrated in FIG. 8, the side wall 10 may be located in contact with an upper surface of the first substrate 11. Thus, a gap can be provided between the side wall 10 of the first substrate 11 and an outer periphery of the first substrate 11 as compared with a case where the side wall 10 is located in contact with a side surface of the first substrate 11. With this gap, when a plurality of the thermoelectric modules 100 are mounted side by side, the possibility that the thermoelectric modules 100 located adjacent to each other propagate heat and affect each other can be reduced. As a result, the thermoelectric module 100 of the present disclosure is excellent in reliability.

As indicated by a portion G illustrated in FIG. 8, the side wall 10 may be located in contact with a side surface of the second substrate 12. Thus, heating and heat absorption can be performed not only from an upper surface of the second substrate 12 but also from the side surface thereof. Thus, the heating and the heat absorption of the external member can be performed at a larger portion. As a result, the thermoelectric module 100 of the present disclosure is excellent in reliability.

As indicated by the portion G illustrated in FIG. 8, an end portion of the side wall 10 in contact with the side surface of the second substrate 12 may be rounded. Thus, the stress can be dispersed and occurrence of the cracks at the end portion can be reduced as compared with a case where the end portion includes a corner portion which is not rounded. As a result, the thermoelectric module 100 of the present disclosure maintains high durability.

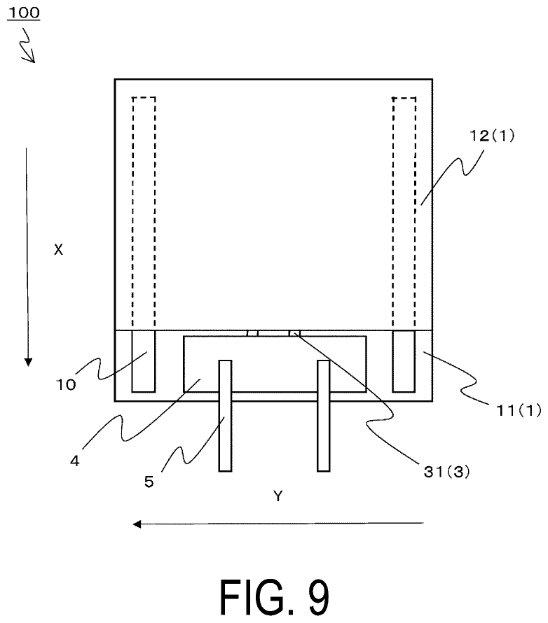

As illustrated in FIG. 9, the side walls 10 may be located inside end portions, respectively, of the first substrate 11 in the second direction (Y). The term “inside” as used herein means that a portion where the first substrate 11 is exposed is provided between an edge of the first substrate 11 and the side wall 10 when viewing the thermoelectric module 100 in a plan view. Thus, the gap described above can be further increased. Thus, the possibility that the thermoelectric modules 100 located adjacent to each other propagate heat and affect each other can be reduced.

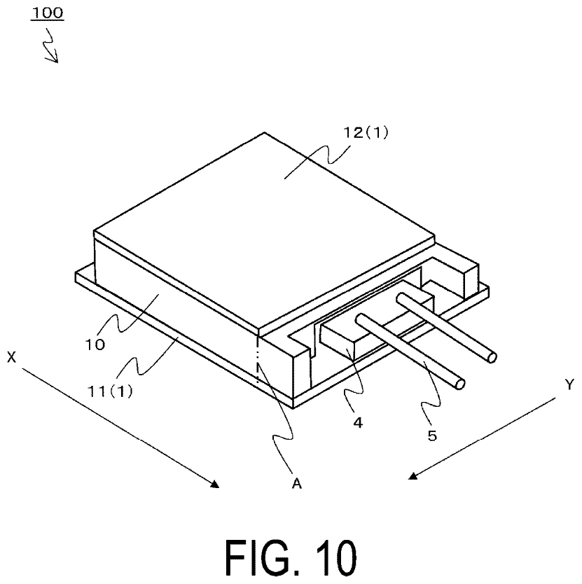

As illustrated in FIG. 10, the side walls 10 may block the first regions 111 facing each other in the first direction and the second direction (Y). Thus, the thermoelectric elements 2 can be surrounded, and thus the thermoelectric elements 2 are less likely to be exposed to the outside air, and the possibility of occurrence of the cracks due to oxidation can be reduced. As a result, the thermoelectric module 100 is excellent in durability.

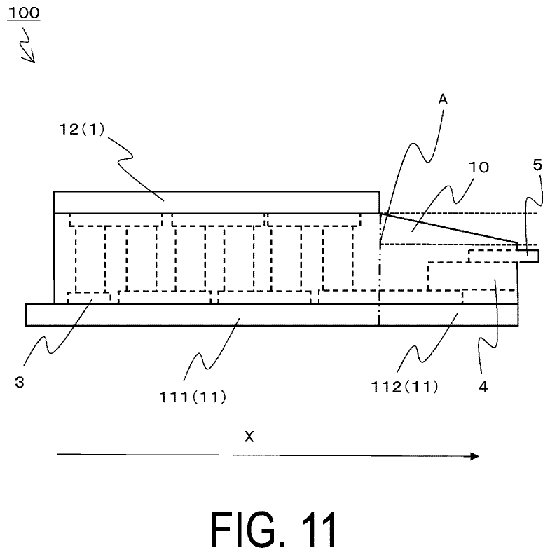

As illustrated in FIG. 11, the height of the side wall 10 may decrease from the boundary A between the first region 111 and the second region 112 toward a direction away from the first region 111. Thus, the side wall 10 does not have a corner portion as compared with a case where the height of the side wall 10 does not change from the boundary A between the first region 111 and the second region 112 toward the direction away from the first region 111, and thus occurrence of cracks can be suppressed. As a result, the thermoelectric module 100 of the present disclosure is excellent in durability. For ease of understanding that the height of the side wall 10 decreases, in FIG. 11, two imaginary lines (dotted lines) when the side wall 10 extends in parallel are added to the first substrate 11.

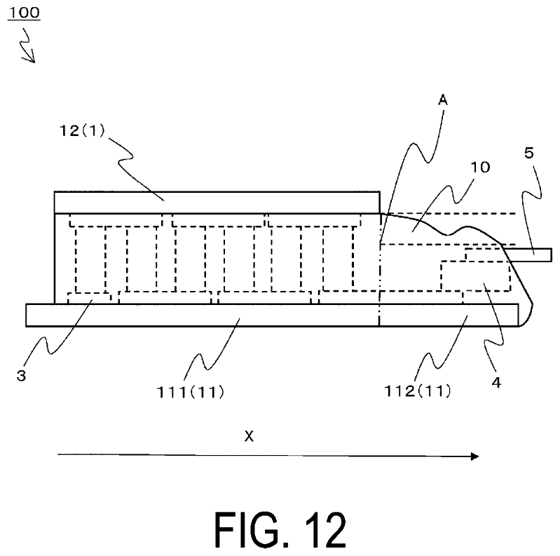

As illustrated in FIG. 12, the side wall 10 in a side view may have a wave shape on the second region 112. The term “wave shape” as used herein means that the contour of the side wall 10 has the wave shape as illustrated in FIG. 11 when viewing the thermoelectric module 100 in a side view. Thus, the contour of the side wall 10 can be changed as compared with the case where the height is constant and does not change from the boundary A toward the direction away from the first region 111, and the surface area can be increased. Thus, high heat dissipation properties are achieved. Thus, deterioration of the side wall 10 due to repetition of a cycle of temperature change of heating and cooling for a long period of time is small. As a result, the thermoelectric module 100 of the present disclosure is excellent in durability. For ease of understanding that the contour has the wave shape in FIG. 12, two imaginary lines (dotted lines) when the side wall 10 extends in parallel are added to the first substrate 11.

As illustrated in FIG. 12, the side wall 10 may be located over a side surface of the second region 112 of the first substrate 11. Thus, a portion of the side wall 10 on the first substrate 11 can be increased, and thus, even when the stress is generated in the support substrate 1 in a wider range, the stress is easily relaxed as compared with a case where the first substrate 11 is located only at a portion facing the second substrate 12. As a result, the thermoelectric module 100 of the present disclosure is excellent in durability.

The side wall 10 may be located over the side surface of the first substrate 11. Thus, a portion of the side wall 10 on the first substrate 11 can be increased, and thus, even when the stress is generated in the support substrate 1 in a wider range, the stress is easily relaxed as compared with a case where the first substrate 11 is located only at a portion facing the second substrate 12. As a result, the thermoelectric module 100 of the present disclosure is excellent in durability.

Next, dimensions of members constituting the thermoelectric module 100 will be described.

A range where the first region 111 of the first substrate 11 and the second substrate 12 is located is such that the vertical length extending in the first direction (X) is from 4 mm to 200 mm, and the horizontal length extending in the second direction (Y) is from 4 mm to 200 mm.

The first substrate 11 includes the second region 112 subsequent to the first region 111. A range where the second region 112 is located is such that the vertical length extending in the first direction (X) is from 1 mm to 30 mm, and the horizontal length extending in the second direction (Y) is from 4 mm to 200 mm. The thicknesses of the first substrate 11 and the second substrate 12 are from 0.1 mm to 5 mm.

In the case where the plurality of thermoelectric elements 2 each have the cylindrical shape, the dimensions of the thermoelectric element 2 are set such that, for example, a diameter is from 0.2 mm to 5 mm and a height is from 0.1 mm to 10 mm.

Since the wiring conductors 3 are located on the first substrate 1111 and the second substrate 12, the wiring conductors 3 are disposed in a range from the entire length of the support substrate 1 from 4 mm to 200 mm and each having a thickness from 0.01 mm to 0.5 mm.

The dimensions of the connector 4 are such that the vertical length extending in the first direction (X) is from 0.9 mm to 24 mm, and the horizontal length extending in the second direction (Y) is from 1 mm to 48 mm. The thickness of the connector 4 is from 0.2 mm to 5 mm.

When the lead member 5 has the circular rod shape, the dimensions of the lead member 5 are such that the diameter is from 0.1 mm to 3 mm and the length is from 20 mm to 500 mm.

In a case of the band shape, the dimensions are such that the vertical length extending in the first direction (X) is from 6 mm to 300 mm, and the horizontal length extending in the second direction (Y) is from 2 mm to 50 mm. The thickness is from 0.2 mm to 5 mm.

The dimensions of the fixing member 6 are such that the vertical length extending in the first direction (X) is from 1 mm to 30 mm, and the horizontal length extending in the second direction (Y) is from 1 mm to 34 mm. The thickness of the connector 4 is from 0.2 mm to 5 mm. The length of an inner periphery corresponding to the inner side of the surrounding portion 61 as illustrated in FIG. 5 is from 0.8 mm to 36 mm.

The dimensions of the resin 8 are such that the vertical length extending in the first direction (X) is from 0.3 mm to 8 mm, and the horizontal length extending in the second direction (Y) is from 4 mm to 200 mm. The height of the resin 8 illustrated in FIG. 4 is from 0.1 mm to 7 mm.

The dimensions of the fitting portion 1121 are such that the vertical length extending in the first direction (X) is from 1 mm to 35 mm, and the horizontal length extending in the second direction (Y) is from 8 mm to 200 mm.

The dimensions of the fitting region 1122 are such that the vertical length extending in the first direction (X) is from 1 mm to 30 mm, and the horizontal length extending in the second direction (Y) is from 1 mm to 35 mm.

The dimensions of the side wall 10 are such that the vertical length extending in the first direction (X) is from 4 mm to 200 mm, and the horizontal length extending in the second direction (Y) is from 0.3 mm to 8 mm. The height of the sidewall 10 illustrated in FIG. 7 is from 0.1 mm to 7 mm.

Next, a fixing method and a manufacturing method of the connector 4 of an example of the thermoelectric module 100 of the present embodiment will be described.

A p-type thermoelectric material and n-type thermoelectric material each having a rod shape are cut with a wire saw so as to each have predetermined heights, thereby manufacturing a p-type thermoelectric element and an n-type thermoelectric element. A nickel layer is formed on a cut surface of each of the p-type thermoelectric element and the n-type thermoelectric element by electrolytic plating.

Next, a metal plate to be the wiring conductor 3 is attached to each of the surfaces of the first substrate 11 and the second substrate 12 facing each other, masking is performed, and then portions other than a portion to be the wiring conductor 3 are removed by etching to form the wiring conductor 3.

Further, solder paste is printed on the wiring conductor 3. Then, each thermoelectric element was arranged on the wiring conductor 3 by using a mounter so that the p-type thermoelectric element and the n-type thermoelectric element were electrically connected to each other in series. The p-type thermoelectric element and the n-type thermoelectric element arranged as described above were sandwiched between a pair of the support substrates 1 and heated in a reflow furnace while pressure was applied to the upper and lower surfaces thereof to bond the wiring conductor 3 and the thermoelectric element 2 to each other with solder.

The connector 4 for supplying a current to the obtained thermoelectric module 100 was bonded with the electrically conductive bonding materials 7 made of solder.

The thermoelectric module 100 of the present embodiment is manufactured by the above-described method.

Next, a method of disposing the thermoelectric elements 2 will be described.

In the plurality of thermoelectric elements 2, a main body part is made of a thermoelectric material including a A2B3 type crystal (A is Bi and/or Sb, and B is Te and/or Se), preferably a bismuth (Bi) and tellurium (Te) based thermoelectric material. Specifically, the p-type thermoelectric element is made of a thermoelectric material including, for example, a solid solution of bismuth telluride (Bi2Te3) and antimony telluride (Sb2Te3). The n-type thermoelectric element is made of, for example, a thermoelectric material including a solid solution of bismuth telluride (Bi2Te3) and bismuth selenide (Bi2Se3).

The thermoelectric material to be the p-type thermoelectric element is obtained by solidifying a p-type thermoelectric material made of Bi, Sb and Te as main materials once melted and solidified in one direction by the Bridgman method to form a rod shaped body having a circular cross section. Same as and/or similarly to the p-type thermoelectric element, the thermoelectric material to be the n-type thermoelectric element is obtained by solidifying an n-type thermoelectric material made of Bi, Te and Se as main materials once melted and solidified in one direction by the Bridgman method to form a rod shaped body having a circular cross section.

A method of forming the slits 9 will be described. Any method such as dicing with a diamond grindstone, chemical etching, or dry etching such as sputtering may be used. For example, the slits 9 can be provided by etching a copper-clad substrate, and in this case, it is desirable that the slits 9 are also formed in a substrate portion serving as a base material of the copper-clad substrate.

### REFERENCE SIGNS

1 Support substrate
11 First substrate
111 First region
112 Second region
1121 Fitting portion
1122 Fitting region
12 Second substrate
2 Thermoelectric element
3 Wiring conductor
31 Extended portion
4 Connector
5 Lead member
6 Fixing member
61 Surrounding portion
7 Electrically conductive bonding material
8 Resin
9 Slit
10 Side wall
100 Thermoelectric module

1. A thermoelectric module comprising:
support substrates;
wiring conductors; and
thermoelectric elements,
wherein the support substrates comprise a first substrate and a second substrate facing each other,
the wiring conductors are located on the first substrate and the second substrate,
the thermoelectric elements are located in contact with the wiring conductors facing each other,
the first substrate comprises a first region in which the thermoelectric elements are located and a second region located subsequent to the first region,
the wiring conductors comprise an extended portion extending over the second region,
the thermoelectric module further comprising a connector, and
a surface of the connector facing the support substrate is surface-connected to the extended portion.

2. The thermoelectric module according to claim 1, wherein the connector is fixed to one of the support substrates via a fixing member.

3. The thermoelectric module according to claim 2, wherein
the connector is connected to the wiring conductors via an electrically conductive bonding material,
the fixing member comprises a surrounding portion surrounding the electrically conductive bonding material, and
the connector is placed on the surrounding portion.

4. The thermoelectric module according to claim 1, wherein a width of the extended portion is smaller than a width of each of the wiring conductors located in the first region.

5. The thermoelectric module according to claim 1, wherein
the extended portion is covered with a resin at a portion near the first region other than a portion overlapping the connector in a plan perspective view, and
the resin covers a portion between the first substrate and the second substrate, the portion facing the connector.

6. The thermoelectric module according to claim 1, wherein the first substrate comprises slits in a lattice shape at a position facing the second region.

7. The thermoelectric module according to claim 1, comprising a fitting portion of the connector in the second region,
wherein the fitting portion comprises side walls located along a direction in which the extended portion extends and sandwiching a fitting region in which the connector is fitted.
